(19) United States
(12) Patent Application Publication
(10) Pub. No.: US 2019/0028681 A1
(43) Pub. Date: Jan. 24, 2019

(54) COOLING DEVICE, ELECTRONIC APPARATUS, AND PROJECTION-TYPE DISPLAY DEVICE

(71) Applicant: NEC Display Solutions, Ltd, Tokyo (JP)

(72) Inventor: Motoyasu UTSUNOMIYA, Tokyo (JP)

(73) Assignee: NEC Display Solution , Ltd., Tokyo (JP)

(21) Appl. No.: 16/080,569

(22) PCT Filed: Dec. 9, 2016
(86) PCT No.: PCT/JP2016/086732

§ 371 Date: Aug. 28, 2018

(30) Foreign Application Priority Data
Mar. 3, 2016 (JP) 2016-041019

(51) Int. Cl. H04N 9/31; G03B 21/16; H05K 7/20

(52) U.S. Cl. CPC H04N 9/3144; H05K 7/20; H04N 9/3197; G03B 21/16

(57) ABSTRACT

A cooling device air-cools a heat-generating portion within an electronic apparatus, the cooling device including a fan that generates a cooling airflow and vibration-generating unit that generates flow-induced vibration in the cooling airflow that is conveyed to the heat-generating portion. The electronic apparatus includes the cooling device and the heat-generating portion that is the object of cooling by the cooling device. A projection-type display device displays an image by projecting the image, the projection-type display device including the cooling device and a liquid crystal unit that forms the images to be projected and that is the heat-generating portion that is the object of cooling by the cooling device.

### TECHNICAL FIELD

The present invention relates to a cooling device for cooling a heat-generating portion and to an electronic apparatus and projection-type display device that are provided with the cooling device.

### BACKGROUND ART

For some time, various types of cooling devices have been investigated for cooling the heat-generating portions that are provided in an electronic apparatus. In particular, air-cooled cooling devices have been adopted in many electronic apparatuses as cooling devices that are both simple and inexpensive. For example, forced-air cooling devices are used in projection-type display devices (projectors) that have come into widespread use for both business and residential uses.

A projection-type display device is a device that displays by projecting an image or picture that has been formed by a picture-forming element onto, for example, a screen. The following explanation regards the configuration and operation of, among projection-type display devices, liquid crystal projector devices that use a liquid crystal panel as the picture-forming element. Projection-type display devices also include configurations that use a DMD (Digital Micro-mirror Device (registered trademark)) as the picture-forming element.

A liquid crystal projector device is provided with, for example, an extra-high-pressure mercury lamp that generates high-luminance white light as the light source for picture projection. The white light emitted from the light source is reflected by a reflector, and after undergoing polarization conversion by a PBS (polarization beam splitter), is separated into colored light of the colors red (R), green (G), and blue (B).

The colored light that has been separated is irradiated into liquid crystal panels that have been prepared for each of R (red), G (green) and B (blue) and undergoes optical modulation on the basis of a video signal. The colored light that has been optically modulated is synthesized by a color-synthesizing prism and projected by way of a projection optical system. Although an example of a configuration that is provided with liquid crystal panels for the colored light of each of the colors R (red), G (green), and B (blue) has been shown here, there are also configurations that use a shared liquid crystal panel for each of the light colors R (red), G (green), and B (blue) in the liquid crystal projector device. In addition, although an example of a configuration has here been shown in which optical modulation is realized using a transmissive liquid crystal panel, there are also configurations that realize optical modulation using a reflective liquid crystal panel in the liquid crystal projector device.

A liquid crystal panel is of a configuration in which liquid crystal molecules are disposed between two substrates in which transparent electrodes are formed, the liquid crystal panel controlling the state of light that is transmitted by using the property by which the orientation of liquid crystal molecules changes when voltage is applied between the electrodes. As a result, a polarizing plate that transmits only polarized light of a specific direction is arranged on the light irradiation side of the liquid crystal panel such that only light that vibrates in the specific direction (polarized light) that corresponds to the orientation of the liquid crystal molecules is irradiated into the liquid crystal panel. In addition, in the liquid crystal panel, changing the orientation of the liquid crystal molecules according to the presence or absence of voltage between the electrodes causes the direction of vibration of the irradiated polarized light to change along with the orientation of the liquid crystal molecules. As a result, a polarizing plate that passes only one polarized light among the polarized lights for which the direction of vibration differs that are emitted from the liquid crystal panel is arranged on the light emission side of the liquid crystal panel. A typical configuration unifies these components, the liquid crystal panel and polarizing plates that are arranged on the light incident side and light emission side of the liquid crystal panel forming one unit (a liquid crystal unit). In the following explanation, the polarizing plate that is arranged on the light incident side of the liquid crystal panel is referred to as the “incident-side polarizing plate”, and the polarizing plate that is arranged on the light emission side is referred to as the “emission-side polarizing plate”.

Because the incident-side polarizing plate and the emission-side polarizing plate each pass only one polarized light and block other polarized lights as described hereinabove, the energy of light that is blocked by the incident-side polarizing plate and emission-side polarizing plate is converted to heat. In other words, during operation of a liquid crystal projector device, the incident-side polarizing plate and the emission-side polarizing plate generate heat. In addition, because a portion of the incident light is blocked by the black matrix that is provided at each pixel border in the liquid crystal panel, the energy of the blocked light is converted to heat. As a result, the liquid crystal panel also generates heat during operation of a liquid crystal projector device. Accordingly, a liquid crystal unit becomes a heat-generating portion of a liquid crystal projector device.

On the other hand, due to the abundant use of organic materials in a liquid crystal panel and polarizing plate, operation over a long time period at the high temperatures caused by heat generation results in damage to the alignment film provided in a liquid crystal panel for aligning liquid crystal molecular groups in a fixed direction and thus greatly impairs functions of the liquid crystal panel, such as the polarized light selectivity of the polarizing plates.

In response to this problem, a cooling device for cooling the liquid crystal unit is provided in a liquid crystal projector device. A cooling device of the background art that is provided in a liquid crystal projector is next described.

FIG. 1 is an external perspective view of a liquid crystal projector device. FIG. 2 is a plan view giving a schematic representation of the internal configuration of the liquid crystal projector device shown in FIG. 1.

As shown in FIG. 1, liquid crystal projector device 1 is of a configuration that is provided with a switch group for operating the device as well as with a terminal group for applying from the outside input such as control signals or video signals that indicate images or pictures that are to be projected.

As shown in FIG. 2, cooling fan 3 for forced-air cooling of liquid crystal unit 2 and air-cooling duct 4 for guiding the cooling airflow (hereinbelow also referred to as “fan airflow”) generated by cooling fan 3 to liquid crystal unit 2 are provided inside the case of liquid crystal projector device 1. Projection lens 10 for projecting to the outside light that has undergone optical modulation is secured to the liquid crystal unit 2. In addition, lamp cooling fan 6 for forced-air cooling of lamp 5 that is the light source and lamp air-cooling duct 7 that guides the cooling airflow generated by cooling fan 6 to lamp 5 are provided inside the case of liquid crystal projector device 1. Liquid crystal projector device 1 is further provided with exhaust fan 9 for forcibly exhausting air inside the case and for cooling power supply unit 8 that supplies the necessary power supply voltage to each constituent component of liquid crystal projector device 1.

The cooling device of liquid crystal unit 2 that is shown in FIG. 2 is next described using FIGS. 3 and 4.

FIG. 3 is a schematic view showing the cooling operation of the liquid crystal unit in the liquid crystal projector device shown in FIG. 2. FIG. 4 is a perspective view that shows an example of the configuration of the cooling device of the liquid crystal unit shown in FIG. 3.

As shown in FIG. 3, liquid crystal unit 2 is of a configuration that consists of equipped incident-side polarizing plate 13, liquid crystal panel 14, and emission-side polarizing plate 15. Liquid crystal units 2 are provided for each of light colors R (red), G (green), and B (blue) that have been color-separated from white light.

As shown in FIGS. 3 and 4, cooling device 11 of liquid crystal unit 2 is provided with cooling fan 3 and air-cooling duct 4, and air-cooling duct 4 is arranged such that duct discharge ports 16 are positioned below liquid crystal unit 2.

Cooling airflow 12 that is generated by cooling fan 3 passes through air-cooling duct 4 and is discharged from duct discharge ports 16. Cooling airflow 12 that is exhausted from duct discharge ports 16 is conveyed to liquid crystal unit 2 from below liquid crystal unit 2. Cooling airflow 12 that is conveyed to liquid crystal unit 2 passes through the gap between incident-side polarizing plate 13 and liquid crystal panel 14 as well as through the gap between liquid crystal panel 14 and emission-side polarizing plate 15 of liquid crystal unit 2 and is drawn in the upward direction of the figure.

However, with the diversification of the forms of use, projection-type display devices (projectors) in recent years increasingly call for greater miniaturization and greater brightness. Advances are being made in the improvement of the brightness of light sources and the miniaturization of picture-forming elements (liquid crystal unit 2) of projection-type display devices (projectors) in order to meet these needs. As a result, the luminous flux density of light that is irradiated upon liquid crystal unit 2 increases, and the thermal load upon liquid crystal panel 14, incident-side polarizing plate 13, and emission-side polarizing plate 15 provided in liquid crystal unit 2 also increases.

On the other hand, there is also an increasing need for lengthening the product life of a projection-type display device (projector) in order to decrease environmental pollution and to cut running costs. Excepting lamp 5, which is a periodically replaced item, the product life of liquid crystal projector device 1 is particularly dependent upon the component life of liquid crystal unit 2. As a result, raising the cooling efficiency of cooling device 11 to extend the component life of liquid crystal unit 2 can lengthen the product life of liquid crystal projector device 1.

Typically, when the forced-air cooling method is adopted as the means of cooling, the airflow amount realized by cooling fan 3 should be increased to raise the cooling capacity. When the airflow amount is increased by raising the rotational speed of cooling fan 3 to realize higher speed of cooling airflow 12 at this time, the operating noise of cooling fan 3 also increases. On the other hand, when the airflow amount is increased by increasing the diameter of cooling fan 3, the size of the electronic apparatus that is equipped with cooling fan 3 increases.

Further, as shown in FIG. 3, in a configuration in which cooling airflow 12 passes parallel to the panel surface (laminar flow) of liquid crystal panel 14 that is the object of cooling, the average heat transfer rate upon the object of cooling is proportional to the square root of the airflow speed, and the temperature rise of the object of cooling is inversely proportional to the square root of the airflow speed. As a result, when the temperature of the object of cooling is lowered to a certain extent, the decrease of the temperature of the object of cooling slows down with respect to the rise in airflow speed. Accordingly, cooling airflow 12 must be made extremely high-speed to further lower the operating temperature of liquid crystal unit 2 (in particular, the operating temperature of liquid crystal panel 14) in order to extend the life of liquid crystal unit 2.

Nevertheless, increasing the speed of cooling airflow 12 raises the concerns of increase in the operating noise of cooling fan 3 or increase in the size of liquid crystal projector device 1 as previously described. In addition, even if provisionally raising the operating noise of cooling fan 3 or increasing the size of liquid crystal projector device 1 is permissible, there is a limit (air cooling limit) to the improvement of the cooling capacity, as described above.

Still further, in recent years, liquid crystal projector devices have been developed that use semiconductor lasers in place of the above-described extra-high-pressure mercury lamps as a light source. A light source that uses a semiconductor laser has advantages such as (1) no load upon the environment due to the use of mercury, (2) the ability to instantaneously light up at high brightness, and (3) long component life.

Accordingly, in a liquid crystal projector device that uses a semiconductor laser as a light source, even longer life of liquid crystal unit 2 is demanded to go with the longer life of the light source. As a result, in a liquid crystal projector device that uses a semiconductor laser as a light source, cooling device 11 of liquid crystal unit 2 that is capable of more efficient cooling is necessary to further lower the operating temperature of liquid crystal panel 14 or incident-side polarizing plate 13 and emission-side polarizing plate 15 so as to extend the life of these portions of the liquid crystal projector device.

A cooling device of an electronic apparatus of the background art has been described above taking as an example a projection-type display device (projector), and in particular, a liquid crystal projector device. Nevertheless, there are many electronic apparatuses other than projection-type display devices that have heat-generating portions. For example, personal computers in recent years incorporate high-performance central processing units, and these central processing units also generate heat. On the other hand, to have a central processing unit operate with stability, the operating temperature of the central processing unit must be maintained within a predetermined range. As a result, with the improvements of the performance and the diversification of the forms of use of electronic apparatuses, cooling devices are sought for effectively cooling the heat-generating portions provided in the electronic apparatuses.

Cooling devices for cooling the heat-generating portions provided in an electronic apparatus have been proposed in Patent Documents 1 and 2.

Patent Document 1 discloses the improvement of cooling performance by causing a stream-generating device to move back and forth parallel to a heat-producing surface while the stream-generating device jets a cooling fluid upon the heat-producing surface to cause the directed position of the cooling fluid to move with respect to the heat-producing surface.

Patent Document 2 discloses a projection-type display device in which turbulence-generating means that generate turbulence are provided that generate turbulence in each of the gap between a liquid crystal panel that is provided in a liquid crystal unit and an incident-side polarizing plate as well as in the gap between the liquid crystal panel and an emission-side polarizing plate whereby cooling performance is improved by the turbulence of the cooling airflow that flows in the gaps. In the invention described in Patent Document 2, blocking objects such as plates, piezoelectric vibrators, or rod-shaped solid objects that block a portion of the airflow are arranged as the turbulence-generating means on the upstream side of airflow in the gap between the liquid crystal panel and the incident-side polarizing plate as well as the gap between the liquid crystal panel and the emission-side polarizing plate.

Although not an invention that relates to a cooling device for cooling a heat-generating portion, a fluid spraying construction is described in Patent Document 3 for changing the direction of sprayed air. Patent Document 3 describes both causing the periodic change of the direction of flow of a fluid by means of a fluid element vibrator and providing a pipe resistance variable means in a loop pipe that is provided in the fluid element vibrator to enable changing the period of change.

In order to cause the stream-generating device to move back and forth in a direction parallel to a heat-producing surface, while a cooling fluid is jetted from the stream-generating device, as in the invention that is disclosed in the above-described Patent Document 1, a relatively large-scale stream-generating device must be prepared. Still further, the invention disclosed in Patent Document 1 necessitates a drive mechanism for causing the stream-generating device to move parallel to the heat-producing surface. The addition of such a drive mechanism entails a still greater increase in the size and cost of the electronic apparatus. In addition, the providing a mechanical drive mechanism raises concerns regarding a decrease of the reliability of the electronic apparatus.

The invention described in Patent Document 2 raises concerns regarding increase in draft resistance and a drop in cooling efficiency due to the arrangement of the turbulence-generating means (blocking objects) in narrow spaces such as the gaps between the liquid crystal panel and the polarizing plates for generating turbulence. Theoretically, the above-described increase in draft resistance can be circumvented by optimizing the size, shape, and arrangement of the turbulence-generating means, but this type of optimized design is extremely problematic.

When the spray construction described in Patent Document 3 is adopted for, for example, the exhaust port of an air-cooling duct to convey air to a heat-generating portion, based on the principles of vibration, the duct must be constricted to convert the cooling airflow to a jet. This type of construction leads to an extreme increase of the draft resistance, similar to the invention described in Patent Document 2 and can result in a decrease of cooling efficiency.

In addition to the issue of cooling performance, there is also the serious problem of dust when an air-cooling method is adopted to cool an electronic apparatus.

More specifically, when dust is mixed in the fan airflow for the object of cooling, this dust adheres to the surface of the object of cooling and becomes the cause of breakdowns or defects. For example, in a case in which the electronic apparatus is a liquid crystal projector device, when dust mixes with the fan airflow, the mixed dust adheres to the surface of liquid crystal panel 14. As shown in FIG. 5, when dust adheres to, of the panel surface 17 of liquid crystal panel 14, light transmission area 18, the shadow of the dust forms an image on the screen and thus severely degrades the quality of the projected image.

In a typical liquid crystal projector device, a dustproof filter for preventing the admixture of dust into the air-cooling duct 4 is installed in the intake unit of cooling fan 3 that is used in cooling liquid crystal unit 2. However, when dust clogs the dustproof filter with the passage of usage time, the draft resistance of the dustproof filter increases and the airflow amount decreases. At this time, dust circumvents the dustproof filter in which the draft resistance is great and enters air-cooling duct 4 from other air passages or gaps of the case, rendering the protection of liquid crystal unit 2 against dust inadequate.

### RELATED ART DOCUMENTS

### Patent Documents

Patent Document 1: JP 2000-252669 A

Patent Document 2: JP 2001-125057 A

Patent Document 3: JPH8-145449A

### SUMMARY

It is an object of the present invention to provide a cooling device that allows miniaturization while improving the dustproof property and cooling performance and to provide an electronic apparatus and projection-type display device that are provided with the cooling device.

A cooling device according to an exemplary aspect of the present invention for achieving the above-described object is a cooling device for air-cooling heat-generating portions in an electronic apparatus and has:

a fan that generates cooling airflow; and

a vibration-generating means that generates flow-induced vibration in the cooling airflow that is conveyed to the heat-generating portions.

A electronic apparatus according to an exemplary aspect of the present invention has:

the above-described cooling device; and

a heat-generating portion that is the object of cooling by the cooling device.

A projection-type display device according to an exemplary aspect of the present invention is a projection-type display device that displays by projecting an image and has:

the above-described cooling device, and

a liquid crystal unit that forms the image to be projected and that is the heat-generating portion that is the object of cooling by the cooling device.

### BRIEF DESCRIPTION OF THE DRAWINGS

FIG. 1 is a perspective view showing an example of an external view of a liquid crystal projector device.

FIG. 2 is a plan view that gives a schematic representation of the internal configuration of the liquid crystal projector device shown in FIG. 1.

FIG. 3 is a schematic view showing the cooling operation of a liquid crystal unit in the liquid crystal projector device shown in FIG. 2.

FIG. 4 is a perspective view showing an example of the configuration of the cooling device of the liquid crystal unit shown in FIG. 3.

FIG. 5 shows an example of the configuration of the liquid crystal unit shown in FIG. 4, FIG. 4(a) being a front view and FIG. 4(b) being a side sectional view.

FIG. 6 is a schematic view showing a model of a structural vibration system for explaining the principle of the present invention.

FIG. 7 is a schematic view showing the movement of cooling airflow obtained by the structural vibration system shown in FIG. 6.

FIG. 8 shows an example of the configuration of a cooling device of the first exemplary embodiment, FIG. 8(a) being a perspective view of a liquid crystal unit and an air-cooling duct, FIG. 8(b) being an exploded view of the air-cooling duct shown in FIG. 8(a), and FIG. 8(c) being a perspective view showing the state in which the principal parts of the air-cooling duct shown in FIG. 8(a) are enlarged.

FIG. 9 is a schematic view showing an example of the operation of the cooling device of the first exemplary embodiment.

FIG. 10 shows an example of the configuration of the duct discharge port shown in FIG. 9, FIG. 10(a) being a sectional view showing the duct discharge port as seen from the front surface, and FIG. 10(b) being a sectional view showing the duct discharge port as seen from the side surface.

FIG. 11 is a schematic view showing in a time series the movement of cooling airflow at the duct discharge port shown in FIG. 10(a).

FIG. 12 shows an example of a configuration of the cooling device of the second exemplary embodiment, FIG. 12(a) being a sectional view showing the duct discharge port as seen from the front surface, and FIG. 12(b) being a sectional view showing the duct discharge port as seen from the side surface.

FIG. 13 is a schematic view showing an example of the movement of cooling airflow that is discharged from the duct discharge port shown in FIG. 12(a).

FIG. 14 shows an example of the configuration of the cooling device of the third exemplary embodiment, FIG. 14(a) being a sectional view showing the duct discharge port as seen from the front surface, and FIG. 14(b) being a sectional view showing the duct discharge port as seen from the side surface.

FIG. 15 is a schematic view showing the movement of cooling airflow that is discharged from the duct discharge port shown in FIG. 14(a).

FIG. 16 shows an example of the configuration of the cooling device of the fourth exemplary embodiment, FIG. 16(a) being a sectional view showing the duct discharge port as seen from the front surface, and FIG. 16(b) being a sectional view showing the duct discharge port as seen from the side surface.

FIG. 17 is a schematic view showing the movement of cooling airflow that is discharged from the duct discharge port shown in FIG. 16(a).

FIG. 18 gives a schematic representation of an example of the configuration of the cooling device of the fifth exemplary embodiment, FIG. 18(a) being a sectional view showing the duct discharge port as seen from the front surface, and FIG. 18(b) being a sectional view showing the duct discharge port as seen from the side surface.

FIG. 19 is a schematic view showing the movement of cooling airflow that is discharged from the duct discharge port shown in FIG. 18(a).

FIG. 20 is a schematic view showing other examples of the configuration of a columnar structure that can be used in the cooling device of the fifth exemplary embodiment.

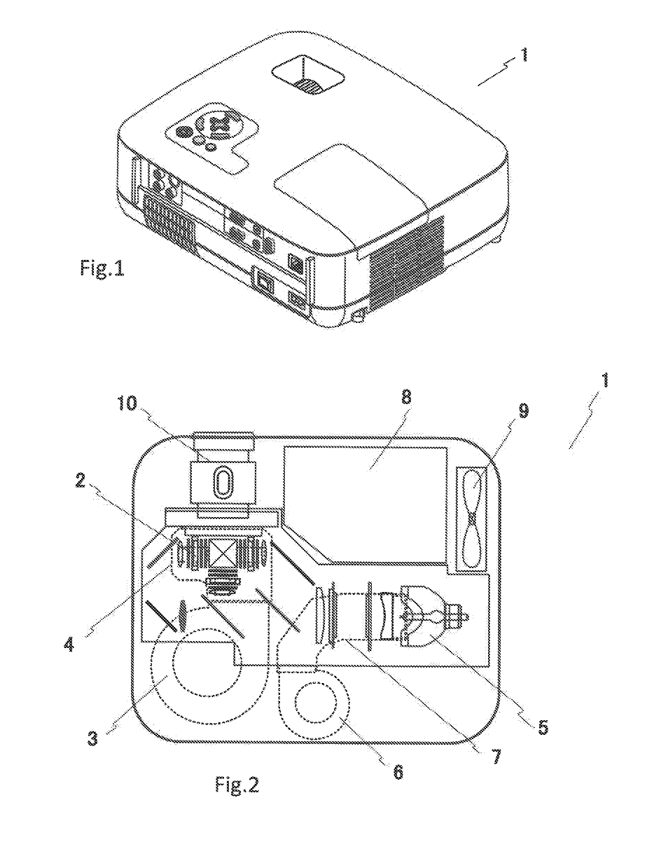

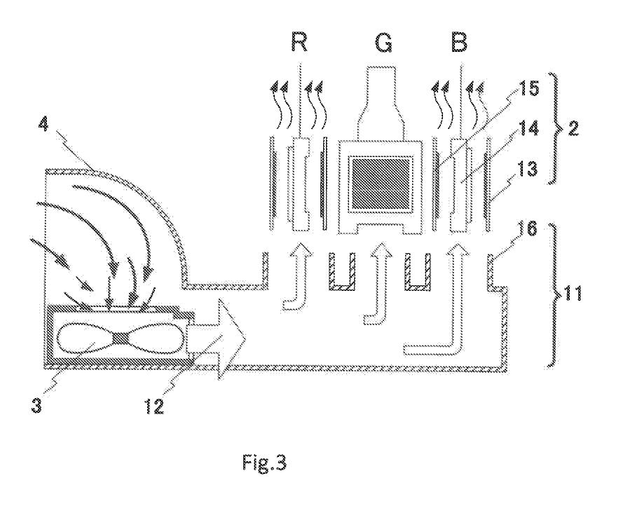

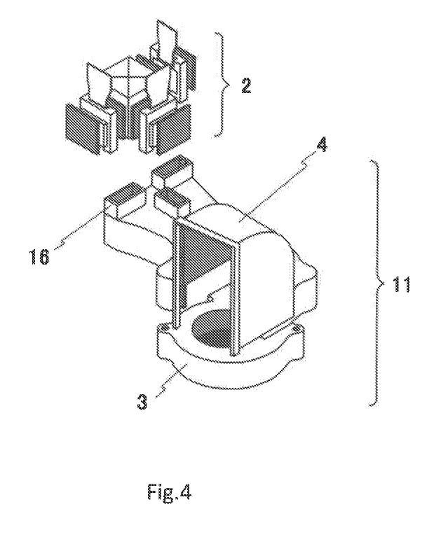

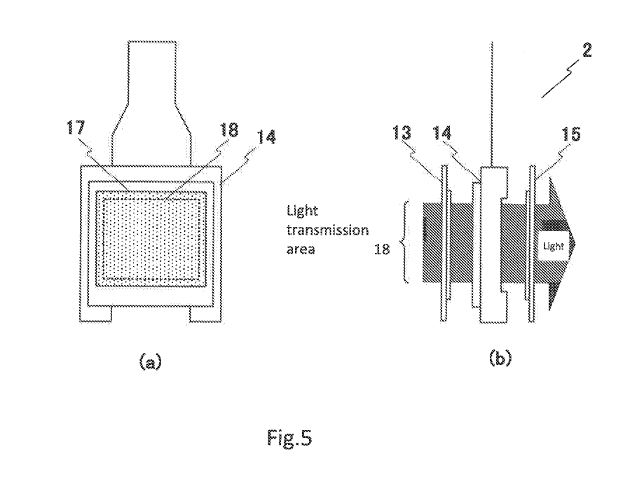

### EXEMPLARY EMBODIMENT

The principles of the present invention are next explained.

In the present invention, a vibration-generating means is provided that generates flow-induced vibration (vortex-induced vibration) in a cooling airflow that is conveyed to a heat-generating portion. A columnar structure that is suspended in the duct discharge port is used as the vibration-generating means. When the cooling air passes through the columnar structure of the duct discharge port, the columnar structure vibrates slightly due to the fluid force of the swirls of air that are generated downstream. When the columnar structure vibrates, the swirls that are generated downstream of the columnar structure also fluctuate, and the fluid force that is induced by the fluctuating swirls is fed back to the structural vibration system that is formed by the columnar structure. As a result, the vibration of the columnar structure is amplified, and the entire structural vibration system brings about self-excited vibration.

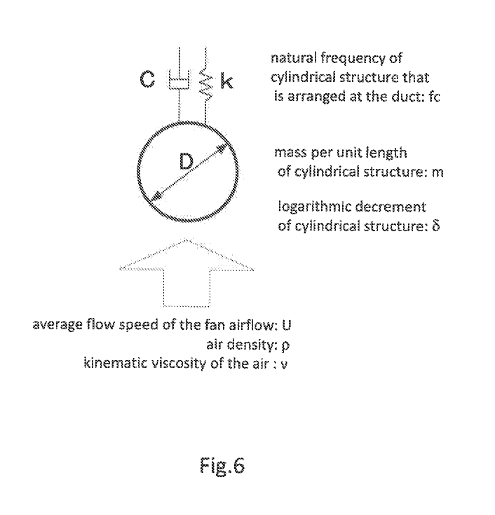

Here, as shown in FIG. 6, if cylindrical structure 19 having a circular cross-section is used as the columnar structure, and the diameter of this cylindrical structure is D, the mass per unit length is m, the logarithmic decrement is δ, the natural frequency is fc, the average flow speed of the fan airflow (cooling airflow) that passes through the columnar structure is U, the air density is ρ, and the kinematic viscosity of the air is v, the conversion damping factor Cn in which the structural damping is made nondimensional and the conversion flow speed Vr in which the flow speed is made nondimensional are represented by the following formulas:

[Numerical Expression 1]

conversion damping factor: Cn=2·m·δ/ρ·D² (1)

[Numerical Expression 2]

conversion flow speed: Vr=U/fc·D (2)

For example, when the conversion damping factor Cn is 1.42, if the conversion flow speed Vr is raised, two excitation regions are generated in the fan airflow that vibrate parallel to the direction of flow (in-line flow). When conversion flow speed Vr is further raised, vibration is generated in the fan airflow in a direction perpendicular to the flow (cross flow). “Vortex-induced vibration” normally refers to the cross-flow vibration that occurs in this region.

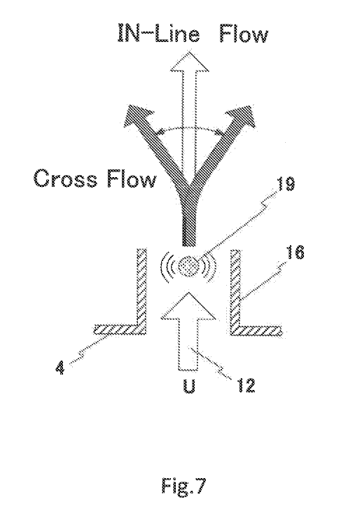

Accordingly, as shown in FIG. 7, diameter (D), mass (m), and rigidity (i.e., the natural frequency fc) of cylindrical structure 19 are designed in conjunction with the flow speed (U) of cooling airflow 12 that is discharged from duct discharge port 16 such that the vortex-induced vibration becomes a maximum at conversion flow speed Vr that accords with conversion damping factor Cn, and if cylindrical structure 19 that is produced based on these design values is arranged at duct discharge port 16, cooling airflow 12 that is discharged from duct discharge port 16 can be caused to generate periodically self-excited vibration in a direction perpendicular to the flow (Cross Flow).

For example, if cooling airflow 12 that passes through the gap between liquid crystal panel 14 and incident-side polarizing plate 13 and the gap between liquid crystal panel 14 and emission-side polarizing plate 15 is caused to generate vortex-induced vibration by using cylindrical structure 19, heat-generating surfaces of liquid crystal unit 2 can be cooled effectively, and moreover, over a broad range. In addition, even if dust that is mixed with cooling airflow 12 should adhere to liquid crystal unit 2 that is the object of cooling, the vortex-induced vibration of cooling airflow 12 acts like a wiper and thus can effectively remove the dust that has adhered to liquid crystal unit 2. Still further, as shown in FIG. 7, the vibration-generating means is of a simple construction in which a columnar structure (cylindrical structure) 19 is suspended in duct discharge port 16, whereby a cooling device can be realized that readily allows both lower price and smaller size.

### First Exemplary Embodiment

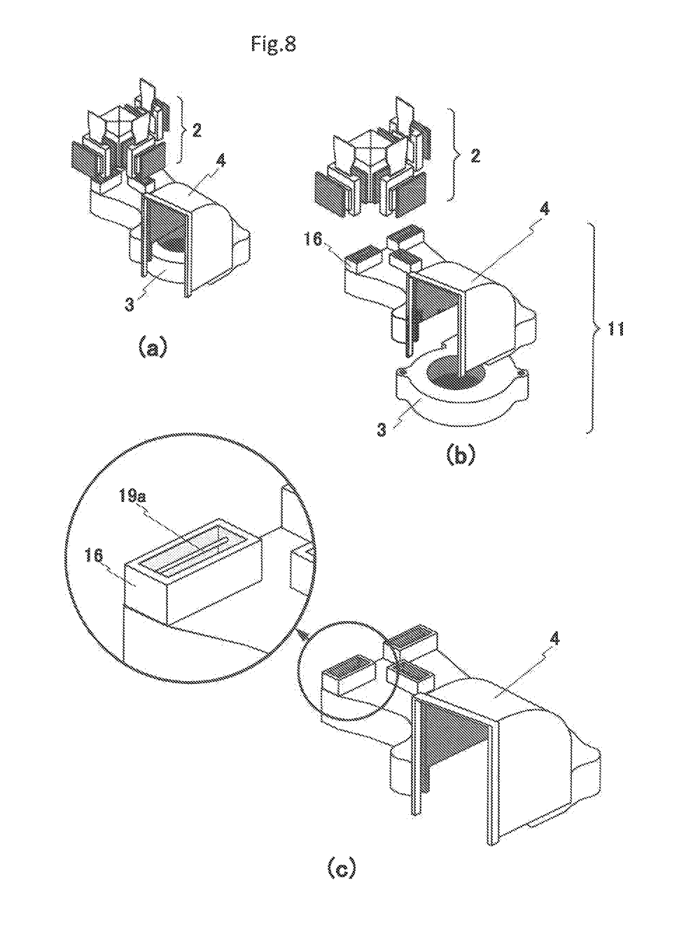

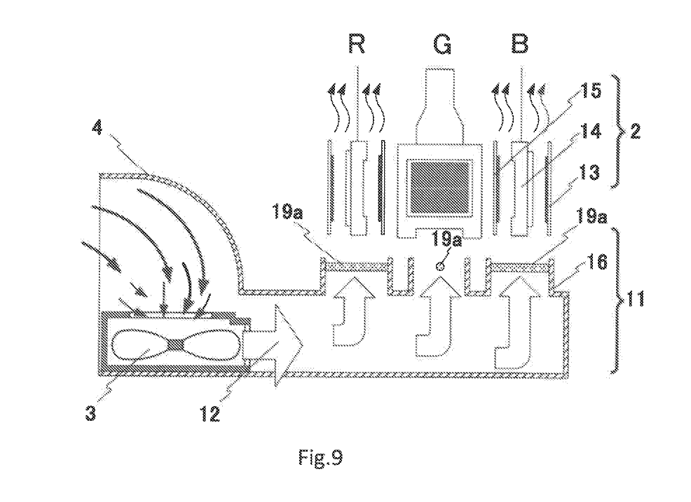

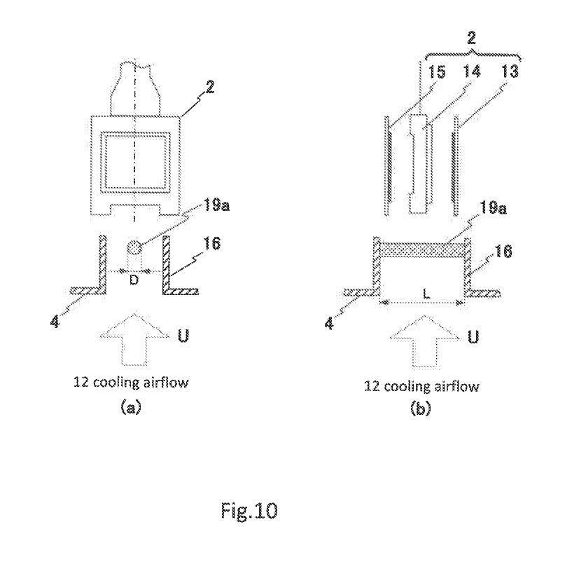

FIG. 8 shows an example of the configuration of the cooling device of the first exemplary embodiment, FIG. 8(a) being a perspective view of a liquid crystal unit and air-cooling duct, FIG. 8(b) being an exploded view of the air-cooling duct shown in FIG. 8(a), and FIG. 8(c) being a perspective view showing the state in which the principal parts of the air-cooling duct shown in FIG. 8(a) are enlarged. FIG. 9 is a schematic view showing an example of the operation of the cooling device of the first exemplary embodiment. FIG. 10 shows an example of the configuration of the duct discharge port shown in FIG. 9, FIG. 10(a) being a sectional view of the duct discharge port as seen from the front surface, and FIG. 10(b) being sectional view of the duct discharge port as seen from the side surface. FIGS. 10(a) and (b) show sectional views of, of the three duct discharge ports 16 shown in FIG. 9, duct discharge port 16 that corresponds to liquid crystal unit 2 that optically modulates green (G) light.

As shown in FIGS. 8-10, the cooling device of the first exemplary embodiment is of a configuration in which cylindrical structure 19a is suspended in duct discharge port 16 of air-cooling duct 4 so as to split the opening into two passageways as a vibration-generating means that generates the above-described flow-induced vibration (vortex-induced vibration) in cooling airflow 12 that is generated by cooling fan 3.

Here, conversion flow-speed (Vr) shown in the above-described formula (2) sets the diameter (D) of cylindrical structure 19a and natural frequency (fc) such that vibration is generated in a direction perpendicular to this flow at speed (U) of cooling airflow 12 at duct discharge port 16. The natural frequency (fc) of cylindrical structure 19a is determined based on, for example, the diameter (D), length (L), mass per unit length (m), spring constant (k), and damping constant (c) of cylindrical structure 19a.

Actual cooling airflow 12 that is discharged from the three duct discharge ports 16 that are arranged corresponding to liquid crystal units 2 of R, G, and B, respectively, differs for each duct discharge port 16, and diameter (D) and natural frequency (fc) therefore must be varied for each cylindrical structure 19a and duct discharge port 16. In the interest of simplifying the explanation, it will here be assumed that identical cylindrical structures 19a are provided for the three duct discharge ports 16 that are arranged corresponding to liquid crystal units 2 of R, G, and B, respectively.

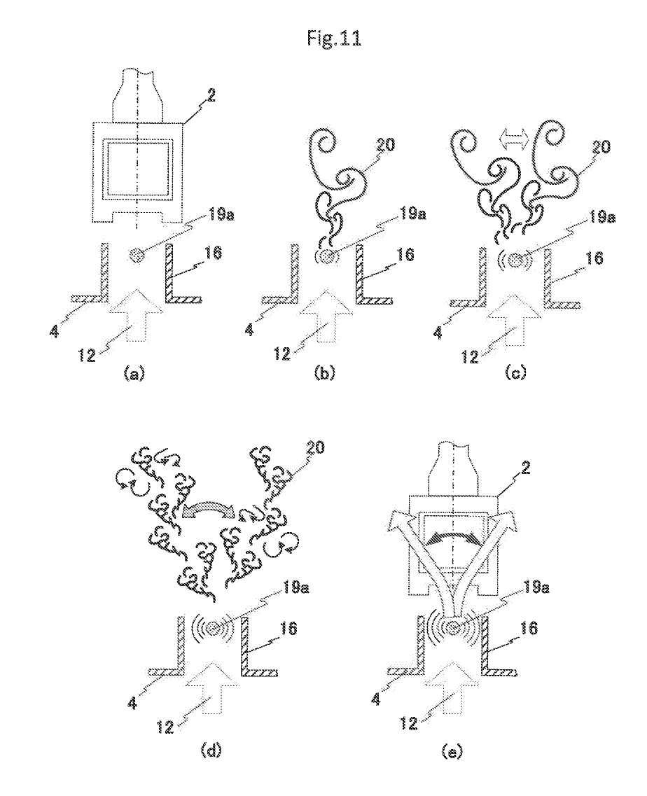

The operation of the cooling device of the first exemplary embodiment is next described using FIG. 11.

FIG. 11 is a schematic view showing in a time series the movement of cooling airflow at the duct discharge port shown in FIG. 10(a).

FIGS. 11(a), (b), (c), (d), and (e) show in a time series the movement of the cooling airflow in duct discharge port 16 in that order. Further, liquid crystal unit 2 is omitted in FIGS. 11(b)-(d).

As shown in FIG. 11(a), cylindrical structure 19a is secured to duct discharge port 16 of air-cooling duct 4 that is arranged below liquid crystal unit 2 that is the object of cooling so as to be positioned approximately on the centerline of liquid crystal unit 2. Cooling airflow 12 that is generated at cooling fan 3 (not shown) is conveyed from duct discharge port 16 to liquid crystal unit 2.

When cooling airflow 12 passes cylindrical structure 19a, swirls 20 are generated on the downstream side of this cylindrical structure 19a as shown in FIG. 11(b). At this time, the fluid force realized by swirls 20 causes cylindrical structure 19a to vibrate slightly, and accompanying the vibration of cylindrical structure 19a that is the generation source of these swirls 20, swirls 20 also change as shown in FIG. 11(c). The fluid force that is excited by swirls 20 that have changed is fed back to the structural vibration system that is made up of cylindrical structure 19a, and the vibration of cylindrical structure 19a is amplified by this fluid force. In this way, the entire system that is made up of cylindrical structure 19a and the downstream-side swirls 20 experience self-excited vibration, as shown in FIG. 11(d). As a result, cross-flow vibration in a direction that is perpendicular to the flow is generated in cooling airflow 12 that is discharged from duct discharge port 16, and moreover, cooling airflow 12 that passes through liquid crystal unit 2 oscillates periodically in a direction perpendicular to the flow, as shown in FIG. 11(e). As a result, cooling airflow 12 that is discharged from duct discharge port 16 passes the heat-generating surface of liquid crystal unit 2 that is the object of cooling while periodically oscillating due to the self-excited vibration (flow-induced vibration).

According to the first exemplary embodiment, by providing a vibration-generating means that generates flow-induced vibration (vortex-induced vibration) in cooling airflow 12 that is conveyed to heat-generating portions (liquid crystal unit 2), the heat-generating surfaces of liquid crystal unit 2 can be cooled over a broad range, and moreover, with high efficiency. In addition, the high turbulence of the cooling airflow (flow-induced vibration flow) that is generated by the vibration-generating means is able to improve the average heat transfer rate with respect to the heat-generating surfaces and thus raise the cooling effect. Further, even should dust that is mixed in cooling airflow 12 adhere to liquid crystal unit 2, this dust is effectively removed by the vibration in a direction perpendicular to the flow of cooling airflow 12 and the dust-proof property of the object of cooling can be increased. Still further, the vibration-generating means is of a simple configuration that involves only the suspension of cylindrical structure 19a in the vicinity of duct discharge port 16, whereby a cooling device that facilitates lower cost and smaller size can be realized.

### Second Exemplary Embodiment

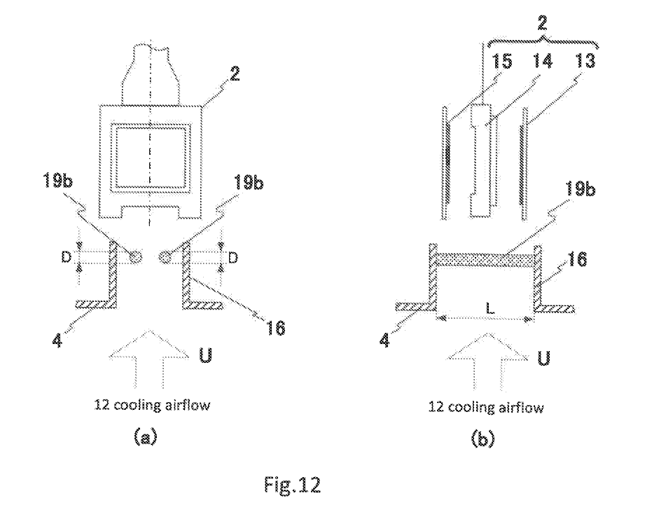

FIG. 12 shows an example of the configuration of the cooling device of the second exemplary embodiment, FIG. 12(a) being a sectional view of the duct discharge port as seen from the front surface, and FIG. 12(b) being a sectional view of the duct discharge port as seen from the side surface. FIGS. 12(a) and (b) show sectional views of, of the three duct discharge ports 16 shown in FIG. 9, duct discharge port 16 that corresponds to liquid crystal unit 2 that optically modulates green (G) light.

As shown in FIGS. 12(a) and (b), the cooling device of the second exemplary embodiment is a configuration in which a plurality of cylindrical structures 19b (two are shown by way of example in FIG. 12(a)) are suspended in duct discharge port 16. The plurality of cylindrical structures 19b are preferably arranged approximately symmetrically with respect to the central axis of liquid crystal unit 2 that is the object of cooling. The plurality of cylindrical structures 19b may be arranged asymmetrically according to the distribution of heat-generating points that are the objects of cooling.

According to the second exemplary embodiment, the arrangement of a plurality of cylindrical structures 19b in duct discharge port 16 enables the generation of flow-induced vibration (vortex-induced vibration) at a plurality of sites in cooling airflow 12 that is discharged from air-cooling duct 4.

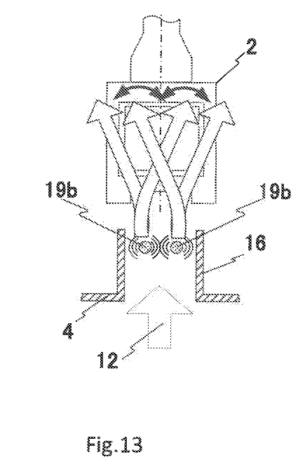

As a result, not only can effects similar to those of the first exemplary embodiment be obtained, but cooling airflow 12 can be conveyed to a broader range with respect to heat-generating portion (liquid crystal unit 2) that is the object of cooling, as shown in FIG. 13.

### Third Exemplary Embodiment

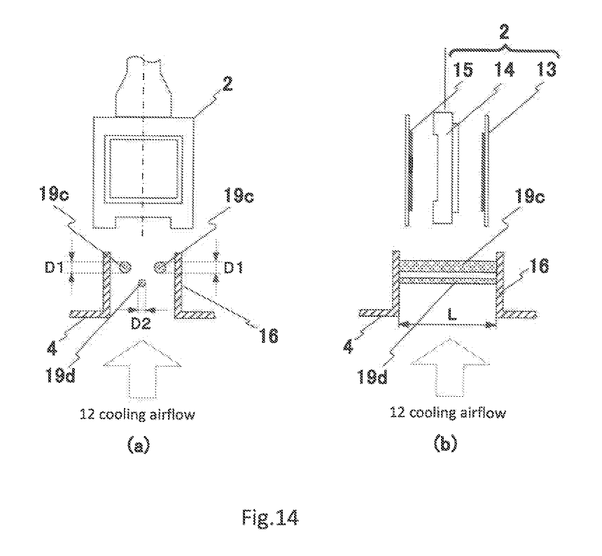

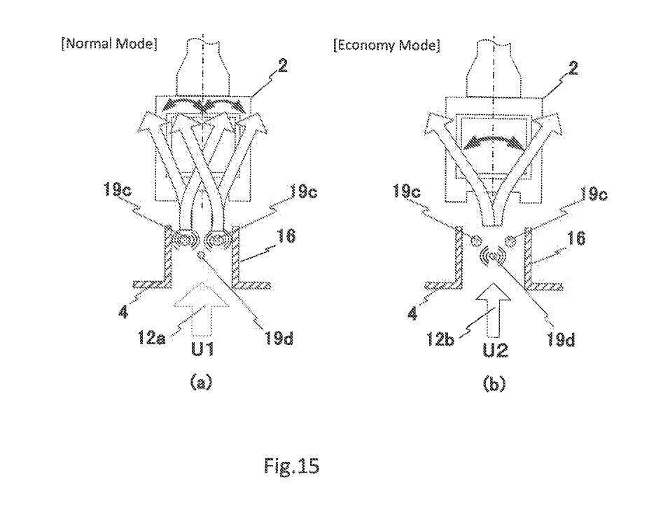

FIG. 14 shows an example of the configuration of the cooling device of the third exemplary embodiment, FIG. 14(a) being a sectional view of the duct discharge port as seen from the front surface, and FIG. 14(b) being a sectional view of the duct discharge port as seen from the side surface. FIGS. 14(a) and (b) show sectional views of, among the three duct discharge ports 16 shown in FIG. 9, duct discharge port 16 that corresponds to liquid crystal unit 2 that optically modulates green (G) light. FIG. 15 is a schematic view showing the movement of the cooling airflow that is discharged from the duct discharge port shown in FIG. 14(a). FIG. 15(a) shows the movement of the cooling airflow that is discharged from duct discharge port 16 when the liquid crystal projector device is operated in the “normal mode” to be described below, and FIG. 15(b) shows the movement of the cooling airflow that is discharged from duct discharge port 16 when the liquid crystal projector device is operated in the “economy mode” to be described below.

As shown in FIGS. 14(a) and (b), the cooling device of the third exemplary embodiment is of a configuration in which a plurality of types of cylindrical structures, in which at least one of the diameter and the natural frequency differs, are suspended in duct discharge port 16. FIGS. 14(a) and (b) show an example of a configuration in which two first cylindrical structures 19c and one second cylindrical structure 19d are arranged in duct discharge port 16.

First cylindrical structures 19c and second cylindrical structure 19d are each designed corresponding to cooling airflows 12a and 12b of different speeds that are set according to the operation mode of the electronic apparatus. For example, in the case of a liquid crystal projector device, in the “normal mode” in which the projector device is operated such that the projected image is in normal brightness, the luminance of the light source is high, the luminous flux density of light irradiated into liquid crystal unit 2 is comparatively great, and the amount of generated heat of liquid crystal unit 2 is therefore great. In this case, the speed (U1) of cooling airflow 12a that is generated by cooling fan 3 must be raised.

On the other hand, in the “economy mode” in which the projector is operated with the luminance of the light source decreased to extend the product life of lamp 5 that is the light source, the luminous flux density of the light that is irradiated upon liquid crystal unit 2 is made lower than in “normal mode”, and the amount of generated heat in liquid crystal unit 2 is therefore decreased. In this case, the cooling capacity can be decreased and the speed (U2) of cooling airflow 12b that is generated at cooling fan 3 may be reduced to decrease the fan noise.

For first cylindrical structures 19c, diameter D1 and natural frequency fc1 are set such that, for example, at the speed (U1) of cooling airflow 12a in “normal mode”, the value of conversion flow speed Vr can be obtained at which the vibration that is in a direction perpendicular to the flow (cross flow vibration) is a maximum.

On the other hand, for second cylindrical structure 19d, diameter D2 and natural frequency fc2 are set such that, for example, at the speed (U2) of cooling airflow 12b in “economy mode”, conversion flow speed Vr can be obtained at which vibration in a direction perpendicular to the flow (cross flow vibration) is a maximum.

According to the third exemplary embodiment, even in a case in which the speed of cooling airflow 12 realized by cooling fan 3 is changed according to the operation mode of the electronic apparatus, flow-induced vibration (vortex-induced vibration) can be generated for the cooling airflow of each speed. Accordingly, the same effects can be obtained as in the cooling device of the first exemplary embodiment for each operation mode in which the speed of cooling airflow 12 differs.

### Fourth Exemplary Embodiment

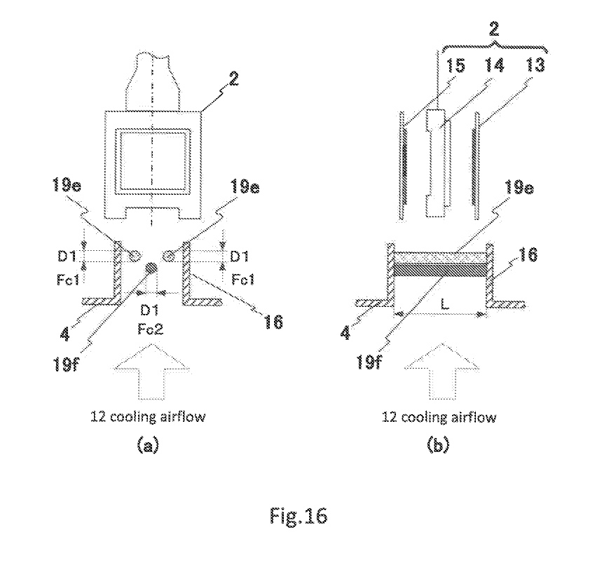

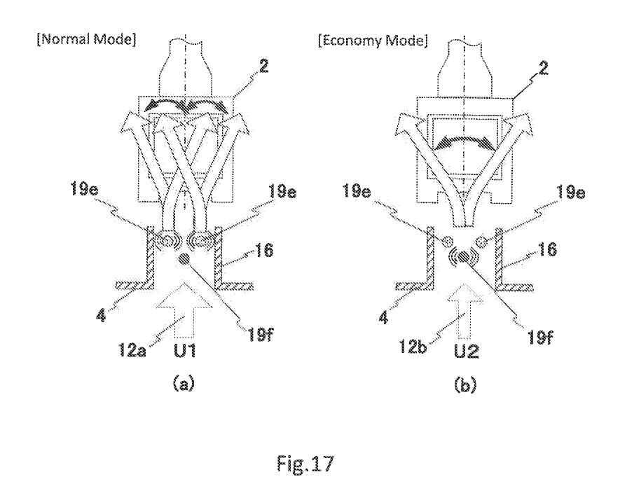

FIG. 16 shows an example of one configuration of the cooling device of the fourth exemplary embodiment, FIG. 16(a) being a sectional view showing the duct discharge port as seen from the front surface, and FIG. 16(b) being a sectional view showing the duct discharge port as seen from the side surface. FIGS. 16(a) and (b) show sectional views of, among the three duct discharge ports 16 shown in FIG. 9, duct discharge port 16 that corresponds to liquid crystal unit 2 that optically modulates green (G) light. FIG. 17 is a schematic view showing the movement of cooling airflow that is discharged from duct discharge port shown in FIG. 16(a). FIG. 17(a) shows the movement of cooling airflow that is discharged from duct discharge port 16 when the liquid crystal projector device is operated in “normal mode”, and FIG. 17(b) shows the movement of cooling airflow that is discharged from duct discharge port 16 when the liquid crystal projector device is operated in “economy mode”.

As shown in FIGS. 16(a) and (b), the cooling device of the fourth exemplary embodiment is of a configuration in which the outer dimensions (diameter D1 and length L) of the plurality of different types of cylindrical structures shown in the third exemplary embodiment are the same and in which only the material of each of the cylindrical structures has been altered such that the natural frequency of each cylindrical structure differs.

In other words, first cylindrical structures 19e and second cylindrical structure 19f are designed such that conversion flow speed Vr becomes the following formula (3) at a plurality of speeds of cooling airflow 12 that are set according to the operation mode of the electronic apparatus.

[Numerical Expression 3]

conversion flow speed: Vr=U1/fc1·D1=U2/fc2·D1 (3)

Here, fc1 is the natural frequency of first cylindrical structures 19e, and fc2 is the natural frequency of second cylindrical structure 19f. In addition, U1 is the speed of cooling airflow 12a when the liquid crystal projector device is operated in “normal mode”, and U2 is the speed of cooling airflow 12b when the liquid crystal projector device is operated in “economy mode”. At this time, cylindrical structures 19 are designed such that a value of conversion flow speed Vr of formula 3 is obtained at which the vibration in a direction perpendicular to the flow of cooling airflow 12 (cross flow) is at the maximum.

According to the fourth exemplary embodiment, as in the third exemplary embodiment, the same effects can be obtained in each operation mode as in the cooling device of the first exemplary embodiment even when the speed of the cooling airflow 12 is changed according to the operation mode.

Still further, according to the fourth exemplary embodiment, because the plurality of cylindrical structures have the same external dimensions, adaptation is facilitated when altering the design. For example, in a liquid crystal projector device, the luminance specifications of lamp 5 in “normal mode” and “economy mode” may be altered. In this case, the amount of generated heat of liquid crystal unit 2 also changes, and the rotational speed of cooling fan 3 may also be changed to change the speed of cooling airflow 12 with respect to liquid crystal unit 2. In such cases as well, if the external dimensions of the cylindrical structures are shared, there is no need to, for example, change the shapes of holes for securing cylindrical structures in air-cooling duct 4. As a result, fabrication cost and the number of design steps can be reduced when the design is to be altered.

### Fifth Exemplary Embodiment

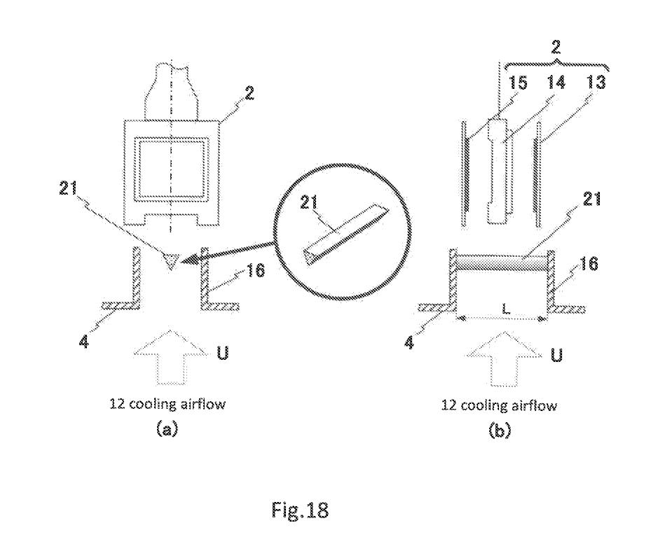

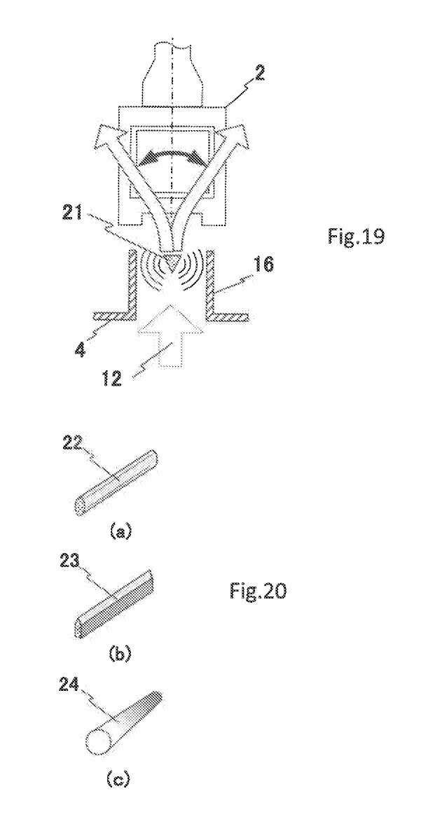

FIG. 18 gives a schematic representation of an example of the configuration of the cooling device of the fifth exemplary embodiment, FIG. 18(a) being a sectional view showing the duct discharge port as seen from the front surface, and FIG. 18(b) being a sectional view of the duct discharge port as seen from the side surface. FIGS. 18(a) and (b) show the state of, among the duct discharge ports shown in FIG. 9, the discharge port for the G light path. FIG. 19 is a schematic view showing the movement of cooling airflow that is discharged from the duct discharge port shown in FIG. 18(a).

The fifth exemplary embodiment as shown in FIGS. 18(a) and (b) is of a configuration that uses triangular columnar structure 21 having a triangular cross section in place of the cylindrical structures shown in the first exemplary embodiment to the fourth exemplary embodiment.

In this case as well, vibration in a direction perpendicular to the flow (cross-flow vibration) can be generated in cooling airflow 12 due to the self-excited vibration of the vortex-induced vibration that is generated on the downstream side of triangular columnar structure 21 that is secured to duct discharge port 16 as shown in FIG. 19.

Typically, in the vicinity of a structure that is placed in a fluid, a layer called the velocity shear layer or boundary layer is formed between the front surfaces of the structure and the main flow due to the viscosity of the fluid. At this time, change in curvature (change of the shape) of the structure causes the velocity shear layer (or boundary layer) to separate from the surface and a strong eddy to grow at the rear surface of the structure, and this eddy is caused to flow downstream by the main flow. As a result, if the cross-sectional shape of a structure placed in a fluid changes, the condition of the swirl produced downstream also changes.

Triangular columnar structure 21 shown in the fifth exemplary embodiment should be applied when sufficiently large vibrations are not generated in a direction perpendicular to the flow (cross flow) with cylindrical structure 19a shown in the first exemplary embodiment in the speed region of cooling airflow 12. In other words, by changing the cross-sectional shape of the columnar structure that is arranged in duct discharge port 16, the conditions of generating self-excited vibration are changed such that flow-induced vibration (vortex-induced vibration) is generated in cooling airflow 12 of a desired speed.

Further, the columnar structure is not limited to triangular columnar structure 21 having a triangular cross section shown in FIGS. 18(a) and (b), and columnar structures of cross-sectional shapes such as shown in FIG. 20 may also be used.

FIG. 20 is a schematic view showing other examples of the configuration of columnar structures that can be used in the cooling device of the fifth exemplary embodiment.

FIG. 20(a) shows an example of oval columnar structure 22 in which the cross section is an oval, and FIG. 20(b) shows an example of polygonal columnar structure 23 in which the cross section is a polygonal shape (FIG. 20(b) shows a pentagonal shape by way of example). The above-described triangular columnar structure 21 is an example of polygonal columnar structure 23.

As described hereinabove, the oval columnar structure shown in FIG. 20(a) or the polygonal columnar structure shown in FIG. 20(b) should be selected as appropriate according to, for example, the ventilation conditions of cooling airflow 12 or the duct shape. Further, as shown in FIG. 20(c), tapered round columnar structure 24 in which the cross section is a circle whose diameter changes in the longitudinal direction may also be used as the columnar structure. Because the diameter changes continuously, tapered round columnar structure 24 can also be applied when the speed of cooling airflow 12 changes continuously.

In the third exemplary embodiment and the fourth exemplary embodiment, configurations were shown that are provided with a plurality of types of columnar structures corresponding to each speed when the speed of cooling airflow 12 changes discretely according to the operation mode.

On the other hand, tapered round columnar structure 24 shown in FIG. 20(c) is suitable for a case in which the speed of cooling airflow 12 changes continuously and vibration in a direction perpendicular to this flow (cross flow) is to be constantly generated.

Triangular columnar structure 21, oval columnar structure 22, polygonal columnar structure 23, and tapered round columnar structure 24 shown in the fifth exemplary embodiment may also be used in place of the cylindrical structure shown in the above-described second exemplary embodiment to fourth exemplary embodiment.

According to the fifth exemplary embodiment, using a columnar structure for which the cross section is not a circle enables the same effects to be obtained as in the first exemplary embodiment to fourth exemplary embodiment even in cases in which, due to, for example, ventilation conditions of cooling airflow 12 or the duct shape, the use of a cylindrical structure does not generate a sufficiently large vibration in a direction perpendicular to the flow in cooling airflow 12.

In the first exemplary embodiment to the fifth exemplary embodiment described hereinabove, explanation regarded examples in which liquid crystal unit 2 that is provided in a liquid crystal projector device is the object of cooling. The cooling device of the present invention is not limited to cooling liquid crystal unit 2 as the object of cooling and may take as the object of cooling any part of an electronic apparatus that is a heat-generating portion that requires cooling.

Although the invention of the present application has been described with reference to exemplary embodiments, the invention of the present application is not limited to the above-described exemplary embodiments. The configuration and details of the invention of the present application are open to various modifications within the scope of the invention of the present application that will be clear to one of ordinary skill in the art.

This application is based upon and claims the benefit of priority from Japanese Patent Application No. 2016-041019, filed on Mar. 3, 2016, the disclosure of which is incorporated herein in its entirety by reference.

1. A cooling device for air-cooling heat-generating portions in an electronic apparatus, comprising:
a fan that generates cooling airflow; and
a vibration-generating means that generates flow-induced vibration in said cooling airflow that is conveyed to a heat generating portion of said heat-generating portions.

2. The cooling device according to claim 1, wherein:
said vibration-generating means comprises a columnar structure that is suspended in a duct discharge port that guides said cooling airflow to said heat-generating portion.

3. The cooling device according to claim 1, wherein:
said vibration-generating means comprises a plurality of types of columnar structures that are suspended in a duct discharge port that guides said cooling airflow to said heat-generating portion.

4. The cooling device according to claim 3, wherein:
said plurality of types of columnar structures differ regarding diameter or natural frequency or diameter and natural frequency.

5. The cooling device according to claim 3, wherein:
said plurality of types of columnar structures have same outer dimensions but are comprised of different materials.

6. The cooling device according to claim 1, wherein:
the cross section of said columnar structure comprises a circle.

7. The cooling device according to claim 1, wherein:
the cross section of said columnar structure comprises a polygon.

8. The cooling device according to claim 1, wherein:
the cross section of said columnar structure comprises an oval.

9. The cooling device according to claim 1, wherein:
said columnar structure comprises a tapered cylinder having a circular cross section whose diameter changes in a longitudinal direction.

10. An electronic apparatus comprising:
the cooling device according to claim 1; and
a heat-generating portion that comprises an object of cooling by said cooling device.

11. A projection-type display device that displays an image by projecting the image, comprising:
the cooling device according to claim 1; and
a liquid crystal unit that forms said image to be projected and that is the heat-generating portion that comprises an object of cooling by said cooling device.
